(19) United States
(12) Patent Application Publication
(10) Pub. No.: US 2004/0022035 A1
(43) Pub. Date: Feb. 5, 2004

(54) Personal computer card

(76) Inventor: Pai-Lien Chang, Lin Kou Hsiang (TW)

Correspondence Address: HARNESS, DICKEY & PIERCE, P.L.C., P.O. BOX 828, BLOOMFIELD HILLS, MI, 48303, US

(21) Appl. No.: 10/308,461

(22) Filed: Dec. 3, 2002

(30) Foreign Application Priority Data
Aug. 2, 2002 (TW) 91211959

(51) Int. Cl. H05K 5/00; H05K 5/04; H05K 5/06

(52) U.S. Cl. 361/752

(57) ABSTRACT

A PC card with a protection shell is described. The PC card has an upper cover, a lower cover, a plastic frame and a circuit board mounted electronic elements. The upper cover has a pair of hooking edges. The lower cover has a pair of sliding corners and a pair of lodging rims extended from the sliding corners. The hooking edges slide on the sliding corners and secure the lower cover. The plastic frame has a pair of fillisters to be coupled with the lodging rims. Hence, the plastic frame is covered with the sliding corners and conjoined with the lodging rims. The circuit board supplies the electronic functions of the card and the upper cover, lower cover and plastic frame construct the protection shell.

### FIELD OF THE INVENTION

The present invention relates to a personal computer card and especially to a protection shell of a personal computer card.

### BACKGROUND OF THE INVENTION

PCMCIA (Personal Computer Memory Card International Association) is an international standards body and trade association that was founded in 1989 to establish standards for Integrated Circuit cards and to promote interchangeability among mobile computers where ruggedness, low power, and small size were critical. A card developed according to PCMCIA standards is called a PCMICA card or PC card for short. The size of the PC card is similar to a credit card. The PC Card Standard defines a 68-pin interface between the peripheral card and the socket into which it is inserted. Three standard PC Card form factors are defined, Type I, Type II and Type III. All PC Cards measure the same length and width, differing only in thickness. Smaller cards can fit in larger sockets.

In addition to electrical and physical specifications, the PC Card Standard defines a software architecture to provide “plug and play” capability across the widest range of products. The PC card enhances the computer function such as the size of a extended memory and the network connection capacity.

The Type I PC card is normally used for memory extension cards and storage card. The Type II is a mainstream PC cards normally used for local area network (LAN) cards, modem cards and sound cards.

FIG. I shows a traditional PC card structure. The traditional PC card includes a upper cover 110, a lower cover 130, and a plastic frame and a circuit board 120. In general, the upper cover, the lower cover and the plastic frame are used to protect the circuit board and the assembly procedure thereof is complicated and the structure is not strong enough. Therefore, enhancing the strength of the PC cards structure and simplifying the assembly procedure of the PC cards are important to the PC card.

### SUMMARY OF THE INVENTION

One object of the present invention is to provide a protection shell with sliding corners, lodging rims and hooks to secure the plastic frame and simplify the PC card assembly procedure.

Another object of the present invention is to provide a protection shell with sliding corners, lodging rims and hooks to enhance the strength of the PC card structure.

The present invention provides a PC card. The PC card comprises an upper cover, a lower cover, a plastic frame, and a circuit board. The upper cover has an internal surface and hooks positioned on both sides of the upper cover. Each hook is formed by bending a edge of the upper cover about 90 degrees, twice. The hooks slide on the sliding corners of the lower cover and then clasp the lower cover when the upper cover is pressed to clasp the lower cover. The lower cover has sliding corners and lodging rims on both side of the lower cover. The lodging rim extends from the sliding corner. The lodging rims contact the internal surface and the hooks clasp the sliding corners when the upper cover and the lower cover are coupled. The plastic frame has fillisters on both side of the plastic frame. Therefore, the lodging rims of the lower cover lodge in the fillisters and the sliding corners cover the plastic frame. The circuit board is mounted on the plastic frame. The circuit board comprises electronic parts and a printed circuit board to execute functions of the PC card. The upper cover and the lower cover are made of metal material to increase the strength of the PC card and protect the same from electromagnetic wave interference.

The sliding corner is formed by bending an edge of the lower cover about 45 degrees to 90 degrees, and a preferred angle of the sliding corner is about 70 degrees. The lodging rim is extended from the sliding corner and is formed by bending an edge of the sliding corner about 30 degrees to 60 degrees. A preferred angle of the lodging rim is about 45 degrees. The upper cover, the lower cover and the plastic frame comprises a protection shell of the PC card.

The present invention utilizes the hooks of the upper cover, the sliding corner and the lodging rim of the lower cover, and the fillisters of the plastic frame to simplify the assembly of the PC card and enhance the strength of the PC card. Further, the upper and the lower covers can protect the same from electromagnetic wave interference.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a traditional PC card structure;

FIG. 2A is a preferred embodiment of protection covers of the PC card according to the present invention prior to assembly;

FIG. 2B is the preferred embodiment of FIG. 2A after assembly; and

FIG. 3 is a partial detailed view of the preferred embodiment of FIG. 2A after assembly.

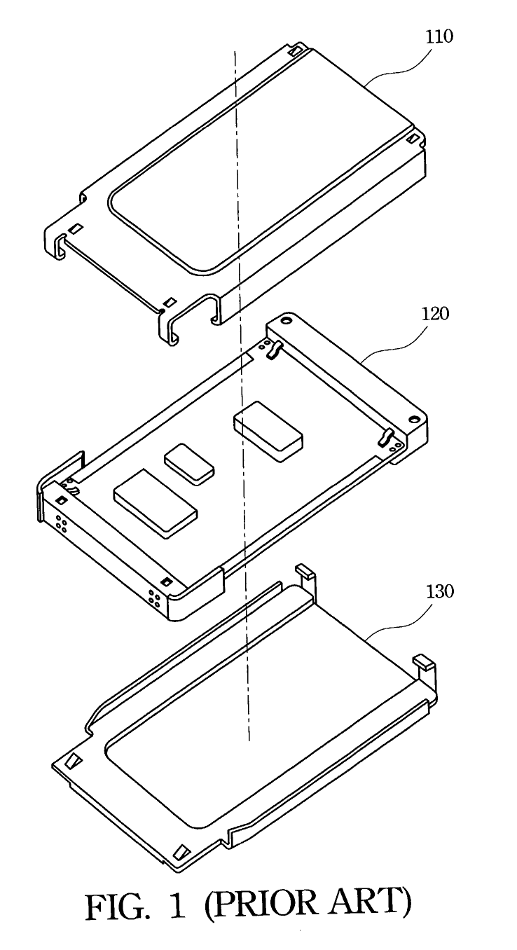

### DETAILED DESCRIPTION OF THE PREFERRED EMBODIMENT

The following description is of the best presently contemplated mode of carrying out the present invention. This description is not to be taken in a limiting sense but is made merely for the purpose of describing the general principles of the invention. The scope of the invention should be determined by referencing the appended claims.

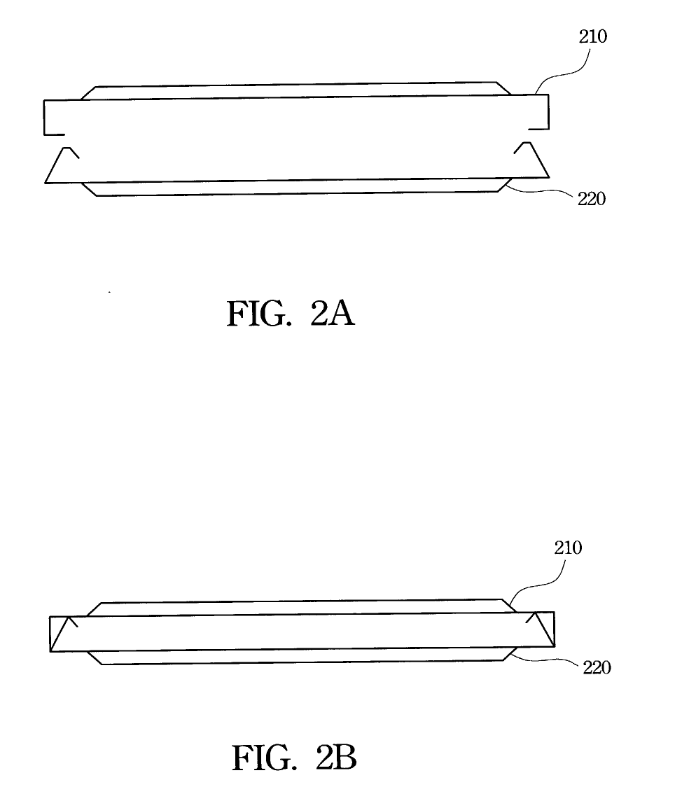

FIG. 2A is a preferred embodiment of protection covers of the PC card according to the present invention prior to assembly. The protection covers includes an upper cover 210 and a lower cover 220. The lower cover 220 has a pair of sliding corners. The upper cover 210 is pressed on the lower cover 220 to connect with the lower cover 220, and therefore a pair hooking edges of the upper cover 210 slides on the sliding corners of the lower cover 220 to hook up with the lower cover 220.

FIG. 2B is the preferred embodiment of FIG. 2A after assembly. The upper cover 210 can easily couple with the lower cover 220 because of the sliding corners as described above while the upper cover 210 and the lower cover 220 are under a pressure force. The covers can be coupled together with the pressure force only, and they can couple with each other very well due to the design of the corners. That is to say, after the covers are coupled together, the only way to separate them is with tools or a very large external force. Otherwise, the upper cover 210 and the lower cover 220 are very stable when coupled together.

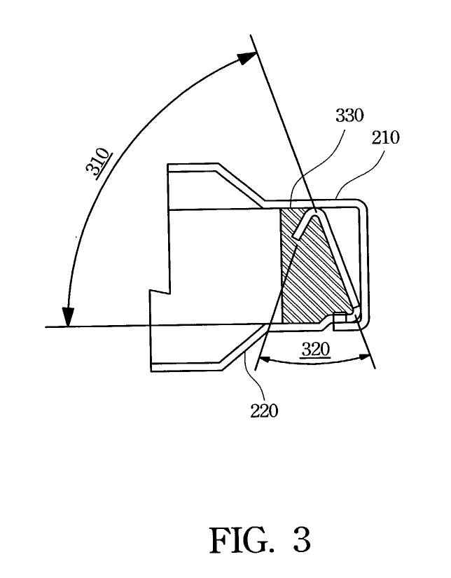

FIG. 3 is a partial detailed view of the preferred embodiment of FIG. 2A after assembly. The upper cover 210 of the PC card according to the present invention has a pair of hooking edges with two continuous 90 degrees bent edges on two sides thereof. The lower cover 220 has a pair of sliding corners and each of the sliding corners has a sliding surface with an angle 310 and a lodging rim extending from the sliding corner has an angle 320. The angle 310 makes the hooking edges of the upper cover 210 able to slide on the sliding surface more easily when the upper cover 210 is coupling with the lower cover 220. The hooking edges then wrap around the lower cover 220. Normally, the angle 310 is larger than about 45 degrees and smaller than about 90 degrees, and the important characteristic of the angle 310 is to help the upper cover 210 couple with the lower cover 220. A preferred angle of the angle 310 is about 70 degrees.

The lower cover 220 further has an angle 320 to form the lodging rims on two sides thereof. The lodging rim can lodge the plastic frame 330 therein. Therefore, the lower cover 220 combines the plastic frame 330 tightly. As the drawing shows, the claspers of the lower cover 220, the lodging rim and the sliding corner, grasp the plastic frame 330 and the plastic frame 330 has complementary fillisters to connect with the claspers of the lower cover. Therefore, the PC card with the plastic frame 330 and the lower cover 220 can enhance the strength thereof and the PC card is difficult to damage. The practicability and the carrying capability of the PC cards are increased. Normally, the angle 320 is between about 30 degrees to 60 degrees, and a preferred angle is about 45 degrees. The upper cover 210 and the lower cover 220 can be made of metal material to form the shape easily and combine with the plastic frame to produce the protection shell of the PC card according to the present invention.

Hence, after the circuit board is put into the lower cover 220 combined with the plastic frame 330, the upper cover 210 is pressed to clasp the lower cover 220, and then the assembly process of the PC card finished. The present invention not only simplifies the assembly process of the PC card but also enhances the structure strength thereof. The circuit board is a printed circuit board with controlling and functional electronic circuits and electronic components thereon.

Due to the limited space of a notebook computer, the function and device of the notebook computer are selected for installation inside the notebook computer. The electronic industry is expanding fast, therefore the notebook computer provides faster and more powerful function. As a result, the occupation rate of the notebook computer increases. PC cards will consequently be more popularly used. The PC card according to the present invention is easy to assemble and has a high structure strength. Further, the upper cover and lower cover protect the circuit board and avoid the electromagnetic wave leakage, enabling the PC card to provide safer work for the notebook computer when the notebook computer and the PC card are working. Furthermore, the PC card can work more safely and with greater stability due to the protection from the electromagnetic waves of other devices.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. A personal computer card comprising:
an upper cover with an internal surface and a hook positioned on both sides of the upper cover;
a lower cover with a sliding corner and a lodging rim on both sides of the lower cover, wherein the lodging rim extends from the sliding corner, the lodging rim contact with the internal surface of the upper cover, and the hook of the upper cover clasps the sliding corner of the lower cover;
a plastic frame with fillisters on both side of the plastic frame, wherein the lodging rim of the lower cover lodges in the fillisters and the sliding corner covers the plastic frame; and
a circuit board mounted on the plastic frame, wherein the circuit board comprises electronic parts and a printed circuit board to execute functions of the personal computer card.

2. The personal computer card of claim 1, wherein the hook of the upper cover slides on the sliding corner of the lower cover and then clasps the lower cover when the upper cover is pressed to clasp the lower cover.

3. The personal computer card of claim 1, wherein the upper cover is made of metal material.

4. The personal computer card of claim 1, wherein the lower cover is made of metal material.

5. The personal computer card of claim 1, wherein the hook of the upper cover is formed by bending edges of the upper cover to an angle of about 90 degrees, twice.

6. The personal computer card of claim 1, wherein the sliding corner is formed by bending an edge of the lower cover to an angle of about 45 degrees to 90 degrees.

7. The personal computer card of claim 6, wherein the sliding corner is in an angle of about 70 degrees.

8. The personal computer card of claim 1, wherein the lodging rim extending from the sliding corner is formed by bending an edge of the sliding corner of the lower cover to an angle of about 30 degrees to 60 degrees.

9. The personal computer card of claim 8, wherein the lodging rim is in an angle of about 45 degrees.

10. A protection shell of a personal computer card comprising:
a metal upper cover with an internal surface and a hook positioned on both sides of the upper cover;
a metal lower cover with a sliding corner and a lodging rim on both side of the lower cover, wherein the lodging rim extends from the sliding corner, the lodging rim contacts with the internal surface, and the hook of the upper cover clasps the sliding corner of the lower cover; and
a plastic frame with fillisters on both sides of the plastic frame, wherein the lodging rim of the lower cover lodges in the fillisters and the sliding corner covers the plastic frame.

11. The protection shell of claim 10, wherein the hook of the metal upper cover slides on the sliding corners of the metal lower cover and then clasps the metal lower cover when the metal upper cover is pressed to clasp the metal lower cover.

12. The protection shell of claim 10, wherein the hook of the metal upper cover is formed by bending edges of the metal upper cover to an angle of about 90 degrees, twice.

13. The protection shell of claim 10, wherein the sliding corner is formed by bending an edge of the metal lower cover to an angle of about 45 degrees to 90 degrees.

14. The protection shell of claim 13, wherein the sliding corner is in an angle of about 70 degrees.

15. The protection shell of claim 10, wherein the lodging rim extending from the sliding corner is formed by bending an edge of the sliding corner of the metal lower cover to an angle of about 30 degrees to 60 degrees.

16. The protection shell of claim 15, wherein the lodging rim is in an angle of about 45 degrees.
